(19) United States
(12) Patent Application Publication
(10) Pub. No.: US 2014/0239467 A1
(43) Pub. Date: Aug. 28, 2014

(54) SEMICONDUCTOR DEVICE

(71) Applicant: Masaki AOSHIMA, Toyota-shi (JP)

(72) Inventor: Masaki AOSHIMA, Toyota-shi (JP)

(73) Assignee: TOYOTA JIDOSHA KABUSHIKI KAISHA, Toyota-shi (JP)

(21) Appl. No.: 14/170,963

(22) Filed: Feb. 3, 2014

(30) Foreign Application Priority Data
Feb. 22, 2013 (JP) 2013-033272

(51) Int. Cl. H01L 23/00; H01L 23/495

(52) U.S. Cl. CPC H01L 23/562; H01L 23/495
USPC 257/666

(57) ABSTRACT

A semiconductor device includes a lead frame, a semiconductor chip soldered to the lead frame, and a metal bar. The metal bar is arranged inside a solder layer so as to extend along one side of the semiconductor chip. When viewed in a stacking direction of the lead frame and the semiconductor chip, the metal bar is arranged so that a part of the metal bar overlaps the semiconductor chip, and the rest of the metal bar does not overlap the semiconductor chip. Then, in a section of the metal bar in a plane perpendicular to a longitudinal direction of the metal bar, an outline of the metal bar on a side of a center of the semiconductor chip is curved so as to project on the side of the center of the semiconductor chip.

### INCORPORATION BY REFERENCE

The disclosure of Japanese Patent Application No. 2013-033272 filed on Feb. 22, 2013 including the specification, drawings and abstract is incorporated herein by reference in its entirety.

### BACKGROUND OF THE INVENTION

1. Field of the Invention

The invention relates to a semiconductor device. The invention especially relates to a semiconductor device in which a semiconductor chip is soldered to a lead frame.

2. Description of Related Art

In a semiconductor device in which a semiconductor chip is soldered to a lead frame, a crack sometimes occurs in a solder layer due to a difference in a coefficient of thermal expansion between the lead frame and the semiconductor chip. Various technologies for restraining occurrence of cracks or restraining damages due to cracks are proposed. (Japanese Patent Application Publication No. 11-186331 A (JP 11-186331 A), Japanese Patent Application Publication No. 2009-106993 A (JP 2009-106993 A), and Japanese Patent Application Publication No. 2006-043733 (JP 2006-043733 A)).

The technology described in JP 11-186331 A is as follows. Projections are provided in a lead frame, and a semiconductor chip is mounted on the projections, and then soldered. Due to the projections, a thickness of a solder layer is equalized, and occurrence of cracks is restrained. The projections are made of a material that does not become wet with solder. Due to the projections that do not become wet with solder, a void occurs in a boundary between the projections and the solder. The boundary of the solder is gently curved along the void. This means that a shape of a fillet becomes gentle, thereby restraining occurrence of cracks.

The technology described in JP 2009-106993 A is as follows. Two metal wires are preliminary buried in a solder material. The solder material is placed on a lead frame, and a semiconductor chip is mounted on the solder material. When a solder is melted, the wires maintain a width between the lead frame and the semiconductor chip constant, thereby forming a solder layer having a constant thickness.

The technology described in JP 2006-043733 A is as follows. Metallic grains are mixed into a solder material. After soldering, even if a crack occurs in a solder layer, the crack stops progressing when the crack runs into the metallic grain. Therefore, damages due to cracks are reduced. In addition, since cracks are likely to occur in corner portions of a semiconductor chip that is rectangular-shaped in a planar view, metallic grains are mixed into the solder material metal to be concentrated around the corner portions of the semiconductor chip.

### SUMMARY OF THE INVENTION

The present invention provides a semiconductor device that restrains damages when a crack occurs. The present invention restrains a damage due to a crack by arranging a metal bar having a specific shape at a specific position in a solder layer.

An aspect of the present invention includes a lead frame, a semiconductor chip soldered to the lead frame, and a metal bar. When viewed in a stacking direction of the lead frame and the semiconductor chip, the metal bar extends along one side of the semiconductor chip, inside a solder layer between the lead frame and the semiconductor chip. In addition, when viewed in the stacking direction of the lead frame and the semiconductor chip, the metal bar is arranged so that a part of the metal bar overlaps the semiconductor chip and the rest of the metal bar does not overlap the semiconductor chip. In a section of the metal bar in a plane that is perpendicular to a longitudinal direction of the metal bar, an outline of the metal bar on a side of a center of the semiconductor chip is curved so as to project on the side of the center of the semiconductor chip. The outline extends from an end portion of the metal bar on the semiconductor chip side to an end portion of the metal bar on the lead frame side.

Cracks are likely to occur in a fillet of the solder layer. The fillet means a region of a solder protruding from between solder joining surfaces of two objects. In the case of the semiconductor device, the fillet means a region of a solder protruding from between the lead frame and the semiconductor chip. In the aspect of the present invention, the metal bar is arranged in the fillet. In a section (a transverse section) of the metal bar, which traverses in a width direction (a direction perpendicular to a longitudinal direction of the metal bar), an outline of the metal bar on a side of a center of the semiconductor chip is curved so as to project to the center of the semiconductor chip. In the aspect of the invention, the outline of the metal bar extends from an end portion of the metal bar on the semiconductor chip side to an end portion of the metal bar on the lead frame side. Due to the metal bar that has the above-mentioned shape and is arranged as stated above, a crack that occurs on a surface of the fillet advances along a boundary between the solder and the metal bar. Because a surface of the metal bar is curved, the crack smoothly proceeds along the curve. The curve of the surface of the metal bar is a curved line that projects to the side of the center of the semiconductor chip. If a crack occurs between the metal bar and the semiconductor chip, the crack advances along the curve of the surface of the metal bar, and, in the end, stops at a contact point between the lead frame and the metal bar. Thus, the semiconductor device according to the aspect of the present invention prevents a crack from advancing to the side of the semiconductor chip. Therefore, a solder layer near the center of the semiconductor chip is not damaged.

An angle, which is made by a tangent of the outline of the metal bar at the contact point between the metal bar and the lead frame and a surface of the lead frame with which the metal bar is in contact, may be an acute angle on the side of the center of the semiconductor chip. Alternatively, the tangent of the outline of the metal bar at the contact point between the metal bar and the lead frame may be on a surface of the lead frame with which the metal bar is in contact. A crack that occurs between the semiconductor chip and the metal bar advances to the side of the center of the semiconductor chip once, along the curve of the surface of the metal bar. However, as the crack advances further along the curve, the crack advances in a direction away from the center of the semiconductor chip. In the end, the crack stops at the contact point between the metal bar and the lead frame. In this aspect, since a crack advances in the direction away from the semiconductor chip, it is further ensured that a crack is prevented from advancing to the center of the semiconductor chip.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a perspective view of a semiconductor device according to a first embodiment of the invention;

FIG. 2 is a partial sectional view taken along the line II-II in FIG. 1;

FIG. 3 is a plan view of a semiconductor device according to embodiments of the invention;

FIG. 4 is a partial sectional view of a semiconductor device according to a second embodiment of the invention;

FIG. 5 is a partial sectional view of a semiconductor device according to a third embodiment of the invention;

FIG. 6 is a partial sectional view of a semiconductor device according to a fourth embodiment of the invention; and

FIG. 7 is a view explaining wettability.

### DETAILED DESCRIPTION OF EMBODIMENTS

First of all, some structures of a semiconductor device according to embodiments of the invention will be listed. Technical elements stated below are independent from each other, and, it can be considered that technical usefulness is achieved by one of or various combinations of the technical elements.

A metal bar may extend across both ends of one side of the semiconductor chip. In this type of form, it is possible to restrain damages due to cracks over the entire region of the one side of the semiconductor chip.

The semiconductor chip is a rectangle when viewed from a stacking direction of a lead frame and the semiconductor chip, and the metal bar may extend along a short side of the semiconductor chip. In a case where the shape of the semiconductor chip is a rectangle in a plan view, stress caused by a difference in a coefficient of thermal expansion between the semiconductor chip and the lead frame is larger in a long-side direction than that in a short-side direction. Hence, cracks are more likely to occur on the short side than on the long side of a fillet. According to the above-mentioned structure, it is possible to restrain damages due to cracks over the entire region on the short side where clacks are likely to occur. As a matter of course, it is desired that metal bars are arranged on both long side and short side.

When a section of the metal bar is either circular or elliptical, and the metal bar is viewed in the stacking direction of the lead frame and the semiconductor chip, the center of the section of the metal bar may be located on an outer side of the semiconductor chip. In a direction that is parallel to a surface of the lead frame with which the metal bar is in contact and is perpendicular to one side of the semiconductor chip, a solder may cover from an edge of the one side of the semiconductor chip to the center of section of the metal bar. When viewed in a direction perpendicular to the lead frame (the stacking direction of the lead frame and the semiconductor chip), if the metal bar is arranged so that the center of the section of the metal bar is located on the outer side of the semiconductor chip, a solder material expands more easily from the edge of the one side of the semiconductor chip to an area directly above the center of the section of the metal bar. Thus, the fillet expands more easily from the semiconductor chip side to the lead frame side. As the fillet expands, cracks are less likely to occur.

A groove, to which the metal bar is fitted, may be provided in the lead frame. Alternatively, a surface of the metal bar, which faces the lead frame, may be horizontal. When either one of the above-mentioned shapes is employed, the metal bar does not roll, and positioning of the metal bar is done easily.

Solder wettability of a surface of the metal bar on the side away from the center of the semiconductor chip may be higher than solder wettability of a surface of the metal bar on the side closer to the center of the semiconductor chip. The side away from the center of the semiconductor chip means the fillet side. The above-mentioned wettability characteristics allow the solder material to flow easily to the fillet side, thereby making the shape of the fillet gentle.

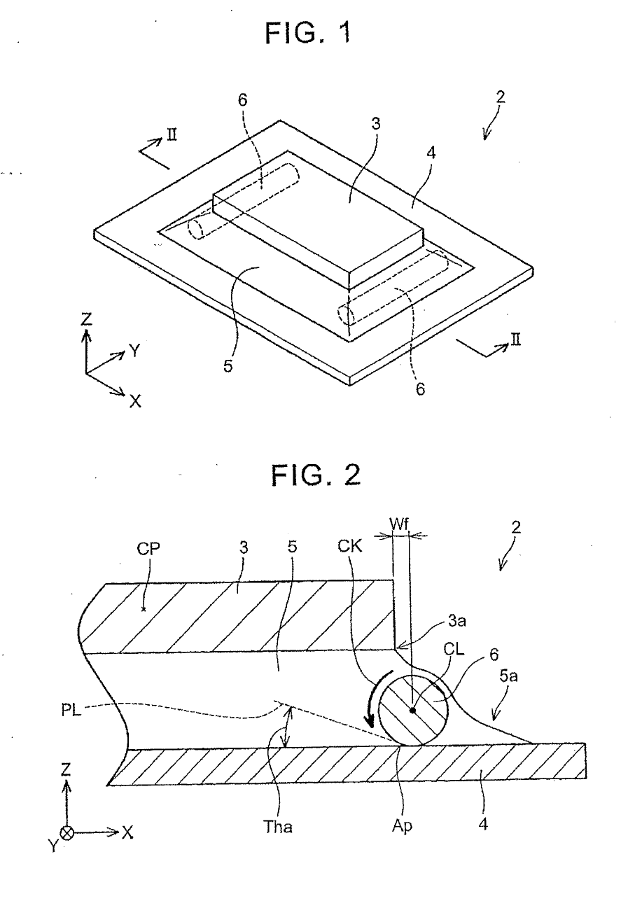

A semiconductor device according to a first embodiment of the invention will be explained with reference to the drawings. FIG. 1 is a perspective view of a semiconductor device 2 according to the first embodiment. The semiconductor device 2 is a device in which a semiconductor chip 3 is soldered onto a lead frame 4. A solder layer 5 is located between the lead frame 4 and the semiconductor chip 3. The semiconductor chip 3 may be IGBT, MOS, a diode, or the like. In the drawings, a thickness and a fillet are depicted in an exaggerated manner so that a state of the solder layer 5 is seen well.

Metal bars 6 are arranged inside the solder layer 5. FIG. 2 shows a sectional view taken along the line II-II in FIG. 1. FIG. 2 shows a partial sectional view. A reference numeral CP in FIG. 2 represents the center of the chip in a plan view of the semiconductor chip 3. Herein below, the center CP of the semiconductor chip will be referred to as a chip center CF. The section in FIG. 2 corresponds to a section that passes through the chip center CP and an edge 3a of the semiconductor chip. The plan view of the semiconductor chip 3 is equal to a view in a direction perpendicular to the lead frame 4, in other words, a view in a stacking direction of the lead frame 4 and the semiconductor chip 3. In FIG. 2, hatching that represents a section is omitted in the solder layer 5 in order to facilitate understanding. Similarly, the sectional views herein below may not have hatching that represents a section.

The metal bars 6 are made of the same material as a bonding wire. The metal bars 6 are located inside a fillet 5a of the solder layer 5. To be more specific, the metal bars 6 are arranged so that, when viewed in the direction perpendicular to the lead frame 4, the metal bars 6 partially overlap the semiconductor chip 3 and the rests of the metal bars 6 do not overlap the semiconductor chip 3. As shown in FIG. 2, a section of the metal bar 6 is a circle, and, the metal bar 6 is arranged so that the center of the section CL of the metal bar 6 does not overlap the semiconductor chip 3 in the plan view of the semiconductor chip 3. In FIG. 2, the center of the section CL is distanced from the chip center CP more than the edge 3a of the semiconductor chip 3 is by a distance Wf. When this arrangement is used, an outline of the fillet 5a starts from the edge 3a of the semiconductor chip 3, passes right above the center of the section CL of the metal bar 6, and continues gently to the lead frame 4. Since the outline of the fillet becomes gentle, cracks are unlikely to occur. This structure is also stated differently as follows. When the section of the metal bar 6 is a circle, and viewed in the direction perpendicular to the lead frame 4, the center of the section CL of the metal bar 6 is located on an outer side of the semiconductor chip 3, and the entire metal bar 6, from the edge 3a of the semiconductor chip 3 to the area right above the center of the section CL, is covered by a solder.

Since the section of the metal bar 6 is a circle, in a section that goes across the metal bar 6 in a width direction of the metal bar 6 (in a transverse section of the metal bar 6), an outline of the metal bar 6 on the chip center CP side, which extends from an end portion of the metal bar 6 on the semiconductor chip side to an end portion of the metal bar 6 on the lead frame side, is curved so as to project on the chip center CP side. In other words, the outline of the metal bar 6 has an arc shape, and projects to the chip center CP side. This means that an angle Tha, which is made by the lead frame 4 and a tangent PL of the section of the metal bar at a contact point AP between the metal bar 6 and the lead frame 4, is an acute angle. Thus, if a crack occurs in the fillet 5a between the semiconductor chip 3 and the metal bar 6, the crack advances along a boundary between the metal bar 6 and the solder layer 5, and stops at the contact point AP between the metal bar 6 and the lead frame 4 in the end. At this time, although the crack goes closer to the chip center CP once along the arc section of the metal bar 6, the crack then advances in a direction away from the chip center CP (see a thick arrow CK in FIG. 2). The crack stops at the contact point AP in the same direction. Because the crack advancing direction is a direction away from the chip center CP, the crack goes towards the fillet and does not go towards the chip center CP side, even if the crack is deviated from the direction towards the contact point AP. In short, the above-mentioned structure leads the crack advancing direction, and prevents the crack from going towards the chip center CP side. When the section of the metal bar 6 is a circle, the tangent PL at the contact point AP coincides with a surface of the lead frame 4. Although it is geometrically wrong, FIG. 2 is intentionally depicted as if there were an angle between the tangent PL and the surface of the lead frame 4 in order to facilitate understanding of the explanation.

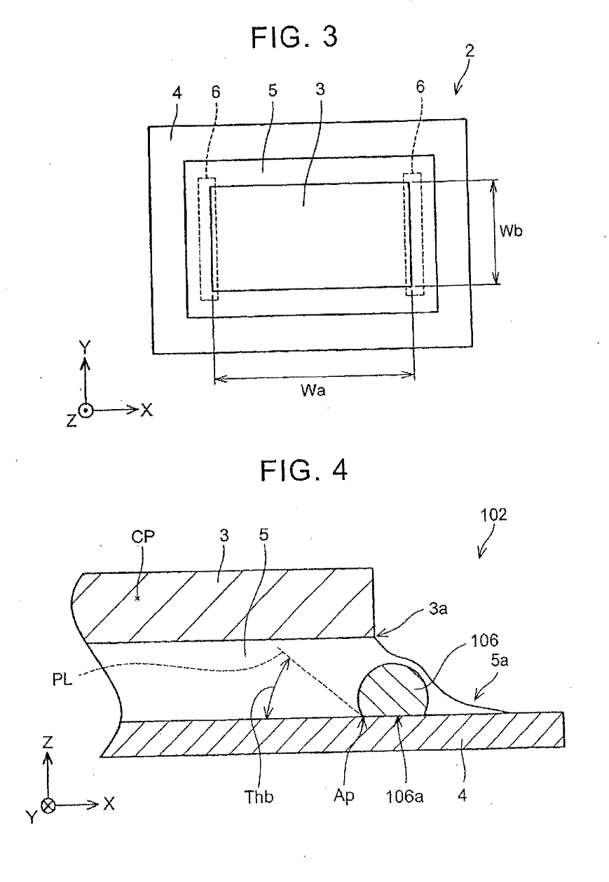

FIG. 3 shows a plan view of the semiconductor device 2. As expressed clearly in FIG. 3, the semiconductor chip 3 is a rectangle in a plan view, and the metal bar 6 extends from end to end of the semiconductor chip 3 along a short side of the semiconductor chip 3. Stress caused by a difference in coefficient of thermal expansion between the semiconductor chip 3 and the lead frame 4 is large in a longitudinal direction of the semiconductor chip 3 (an X axis direction in the drawing). Therefore, cracks are likely to occur on the short side of the semiconductor chip 3. By arranging the metal bar 6 along the short side, damages due to cracks are reduced in a region where occurrence of cracks is likely.

FIG. 4 is a partial sectional view of a semiconductor device 102 according to a second embodiment of the invention. The sectional view in FIG. 4 corresponds to the sectional view in FIG. 2. In this embodiment, a bottom surface of a metal bar 106, in other words, a surface facing the lead frame 4, is shaved to be horizontal, and the metal bar 106 is in contact with the lead frame 4 through the horizontal bottom surface. Compared to the metal bar 6 in the first embodiment, the metal bar 106 does not roll even when a solder is melted.

Also in the semiconductor device 102 according to the second embodiment, in a section that goes across the metal bar 106 in a width direction of the metal bar 106 (in the section in FIG. 4), an outline of the metal bar 106 on a chip center CP side, which extends from an end potion of the metal bar 106 on the semiconductor chip 3 side to an end portion of the metal bar 106 on the lead frame side, is curved so as to project to the chip center CP side. An angle Thb made by the surface of the lead frame and a tangent PL of the curve at a contact point AP between the metal bar 106 and the lead frame 4 forms an acute angle on the chip center CP side. Due to the shape and arrangement of the metal bar 106, a crack which occurs in the fillet advances in a direction away from the chip center CP in the end, and protects a region near the chip center CP from cracks.

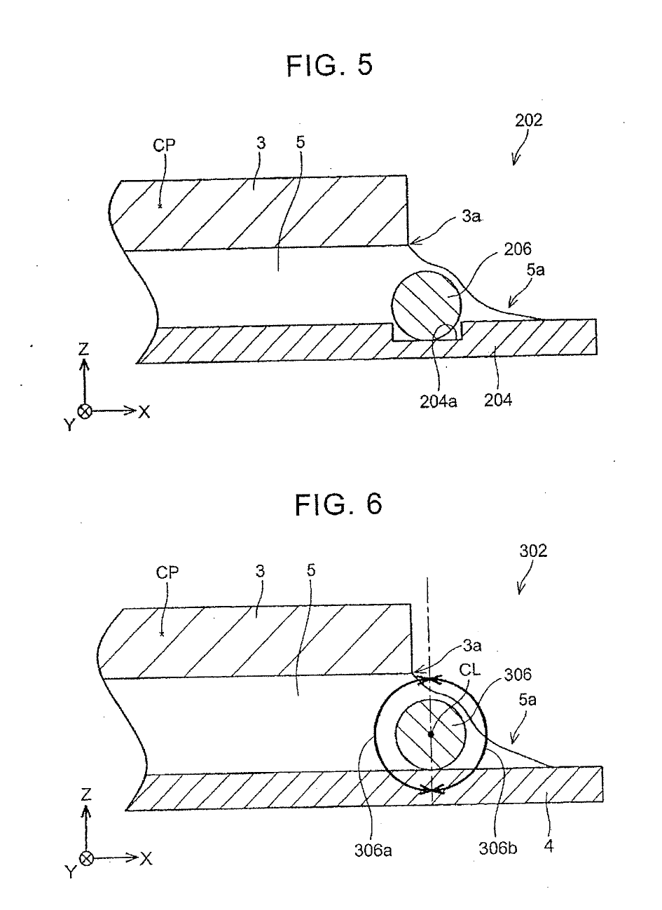

FIG. 5 is a sectional view of a semiconductor device 202 according to a third embodiment of the invention. In this embodiment, a groove 204a, to which a metal bar 206 is fitted, is provided in the lead frame 204. The rest is the same as the semiconductor device 2 according to the first embodiment. The groove 204a has the same advantage as that of the horizontal bottom surface of the metal bar 106 according to the second embodiment. In short, the groove 204a prevents the metal bar 206 from rolling while a solder is melted.

FIG. 6 shows a sectional view of a semiconductor device 302 according to a fourth embodiment of the invention. A sectional view in FIG. 6 corresponds to the section in FIG. 2. In this embodiment, a metal bar 306 is characterized by surface wettability. The metal bar 306 has a circular section, and wettability of a surface 306b of a half circle on a side away from a chip center CP is higher than wettability of a surface 306a of a half circle on a side close to the chip center CP. Higher wettability means better adherence. By using the metal bar 306 having the above-mentioned wettability characteristics, a solder material is easily flown towards the side of the metal bar 306 away from the chip center CP, in other words, the fillet side, and the fillet expands gently from an edge 3a of the semiconductor chip to a lead frame 4. When the fillet expands gently, cracks are little likely to occur.

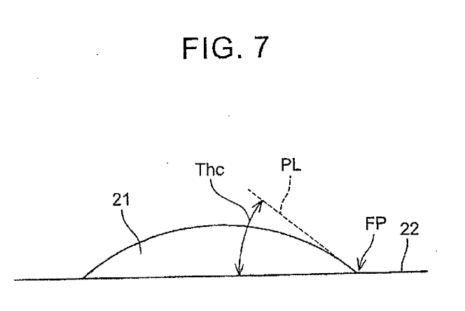

As shown in FIG. 7, the wettability is evaluated by a contact angle The when a melted solder material 21 is placed on a base material 22. The contact angle is an angle that is made by a solder material tangent PL and a surface of the base material 22 directly below a solder material. The solder material tangent PL is a tangent at a boundary FP of the solder material 21 on the surface of the base material.

The semiconductor devices according to the embodiments of the invention have been explained so far. Any of the semiconductor devices according to the embodiments prevents a crack, which has occurred on the surface of the fillet, from advancing towards the chip center CP inside the solder layer, thereby reducing a damage caused by the crack.

Points to be noted with regard to the technologies explained in the embodiments of the invention will be stated. A metal wire (i.e., metal bar) in the embodiment has a circular section. The outline shape of the section of the metal wire is preferably either a circle or an ellipse, but may be a curved line that satisfies conditions stated in the embodiments. The outline shape of the section of the metal wire may be a curved line so that the outline shape on the side closer to the chip center projects to the chip center side, in order to allow a crack to advance easily along the outline. It is preferred that the curved line is continuous in a mathematical sense, in other words, a differentiable curved line. When the outline is bent, a crack might move away from the metal wire, starting from a bent point. It is more preferred that an angle, which is made by the surface of the lead frame, and the tangent at the contact point between the curved line of the outline shape of the section of the metal wire and the lead frame, is an acute angle on the chip center side.

Manufacturing costs are reduced when a material for the metal wire is the same as a material for a bonding wire that connects a terminal of the semiconductor chip with a terminal of the lead frame.

In any of the semiconductor devices according to the embodiment of the invention, a thickness of the solder layer is larger than a diameter of the metal wire, and the metal wire and the semiconductor chip are not in contact with each other. The metal wire and the semiconductor chip may be in contact with each other.

Although the specific embodiments of the present invention have been explained in detail, they are embodiments only, and do not limit the present invention. The present invention includes the specific embodiments listed above with various modifications and changes. Technical usefulness is achieved by one of or various combinations of the technical elements explained in this description and the drawings.

What is claimed is:

1. A semiconductor device comprising:
a lead frame;
a semiconductor chip soldered to the lead frame; and
a metal bar that extends inside a solder layer along one side of the semiconductor chip and is arranged so that a part of the metal bar overlaps the semiconductor chip and the rest of the metal bar does not overlap the semiconductor chip when viewed in a stacking direction of the lead frame and the semiconductor chip, wherein
in a section of the metal bar in a plane that is perpendicular to a longitudinal direction of the metal bar, an outline of the metal bar on a side of a center of the semiconductor chip is curved so as to project on the side of the center of the semiconductor chip, the outline of the metal bar extending from an end portion of the metal bar on the semiconductor chip side to an end portion of the metal bar on the lead frame side.

2. The semiconductor device according to claim 1, wherein
an angle, which is made by a tangent of the outline at a contact point between the metal bar and the lead frame and a surface of the lead frame with which the metal bar is in contact, is an acute angle on the side of the center of the semiconductor chip.

3. The semiconductor device according to claim 1, wherein
a tangent of the outline at a contact point between the metal bar and the lead frame is on a surface of the lead frame with which the metal bar is in contact.

4. The semiconductor device according to claim 1, wherein
the metal bar extends across both ends of the one side of the semiconductor chip.

5. The semiconductor device according to claim 4, wherein
the semiconductor chip is a rectangle when viewed in the stacking direction of the lead frame and the semiconductor chip, and
the metal bar extends along a short side of the rectangle of the semiconductor chip.

6. The semiconductor device according to claim 1, wherein
the section of the metal bar is one of a circle and an ellipse,
a center of the section of the metal bar is located on an outer side of the semiconductor chip when viewed in the stacking direction of the lead frame and the semiconductor chip, and
a solder covers from an edge of the one side of the semiconductor chip to the center of the section of the metal bar in a direction that is parallel to a surface of the lead frame with which the metal bar is in contact, and perpendicular to the one side of the semiconductor chip.

7. The semiconductor device according to claim 1, wherein
the metal bar is arranged so as to be fitted to a groove that is provided in the lead frame.

8. The semiconductor device according to claim 1, wherein
a surface of the metal bar, which faces the lead frame, is horizontal.
